(19) United States
(12) Patent Application Publication
(10) Pub. No.: US 2004/0241964 A1
(43) Pub. Date: Dec. 2, 2004

(54) Method and apparatus for forming film having low dielectric constant, and electronic device using the film

(76) Inventors: Takashi Sugino, Osaka (JP); Masaki Kusuhara, Tokyo (JP); Masaru Umeda, Tokyo (JP)

Correspondence Address: RANDALL J. KNUTH P.C., 3510-A STELLHORN ROAD, FORT WAYNE, IN, 46815-4631, US

(21) Appl. No.: 10/482,867

(22) PCT Filed: Jul. 5, 2002
(86) PCT No.: PCT/JP02/06839

(30) Foreign Application Priority Data
Jul. 5, 2001 (JP) 2001-205471

(51) Int. Cl. H01L 21/322

(52) U.S. Cl. 438/475

(57) ABSTRACT

A film formation method and a film formation apparatus facilitate the formation of a boron carbon nitrogen thin film having an extremely low dielectric constant. The method includes the steps of generating plasma in a film formation chamber, making nitrogen atoms react with boron and carbon in the film formation chamber, forming a boron carbon nitrogen film on a substrate, and then holding the obtained film in a heated state. The holding temperature is advantageously set in the range of 250° C. to 550° C.

### BACKGROUND OF THE INVENTION

1. Field of the Invention

The present invention concerns a film formation method and apparatus for forming a boron carbon nitrogen film and an electronic apparatus using the same.

2. Description of the Related Art

SiO₂ or SiN films formed by a plasma CVD (Chemical Vapor Deposition) method have been used as an interlayer insulator thin film or a protection film of the wiring in the conventional semiconductor integrated circuit. However, accompanying with higher integration of transistors, a wiring delay was provoked by the capacitance between wirings, and it has been problematic as a factor which impedes improvement in the switching speed of elements. Moreover, an improvement of the wiring delay in liquid crystal display panels is also desirable.

In order to solve this problem, the wiring interlayer insulator thin film needs to be reduced in its dielectric constant, and new materials presenting a low dielectric constant are required as an interlayer insulation film.

Organic materials and porous materials attract attention in such a situation, and they can realize an extremely low dielectric constant (relative permittivity κ not more than 2.5). However, they are inconvenient in respect of chemical/mechanical resistance and thermal conductivity. Moreover, in recent years, an extremely low dielectric constant of 2.2 was attained with the boron nitride thin film. Yet, it is known that there is a problem in moisture absorption resistance with this type of film.

Although the boron carbon nitrogen thin film is excellent in thermal resistance and moisture absorption resistance and presents an extremely low dielectric constant and thus attracts attention in such a situation, the film formation technology by the plasma CVD method is not actually established, and a further decrease in dielectric constant is desired.

The present invention has been devised in view of the aforementioned situation and has an object of providing a film formation method and a film formation apparatus that can deposit a boron carbon nitrogen thin film of a low dielectric constant.

### SUMMARY OF THE INVENTION

The film formation method of the present invention for solving the aforementioned problems includes the steps of generating plasma in a film formation chamber, making nitrogen atoms react with boron and carbon in the film formation chamber, forming a boron carbon nitrogen film on a substrate, and thereafter maintaining it in a heated state.

A similar decreasing effect dielectric constant can be obtained in both cases of executing the heating step in the film formation chamber following the film formation time or introducing the heating step in any portion of the process steps after the film formation.

Besides, in the film formation method of the present invention for attaining the aforementioned object, it is preferable to set to the maintaining temperature between 250° C. and 550° C., after the film formation. A more preferable temperature is 350° C. to 450° C., and 400° C. to 450° C. is still more preferable. Below 250° C., the reduction in the dielectric constant is sometimes unremarkable, while over 550° C., an increase of dielectric constant may occur.

The film formation apparatus of the present invention includes a plasma generation means for generating plasma in a film formation chamber, an introduction means for introducing nitrogen, boron and carbon materials, a means for holding a substrate below or within a plasma, and a heating means for heating the substrate holding part.

The apparatus is further characterized by having a heater in the substrate holder of the film formation apparatus.

In addition, it has a new effect of shortening the temperature rising time and temperature lowering time by providing an infrared lamp as the heating means of the substrate holder of the film formation apparatus.

### BRIEF DESCRIPTION OF DRAWINGS

The above-mentioned and other features and advantages of this invention, and the manner of attaining them, will become more apparent and the invention will be better understood by reference to the following description of multiple embodiments of the invention taken in conjunction with the accompanying drawings, wherein:

FIG. 1 is a cross-sectional view showing a film formation apparatus according to an embodiment 1 of the present invention;

FIG. 2 is a graph showing the ratio of relative permittivity before and after the heat treatment in respect to the heat treatment temperature;

FIG. 3 is a cross-sectional view showing a film formation apparatus according to an embodiment 2 of the present invention;

FIG. 4 is a cross-sectional view showing a film formation apparatus according to an embodiment 3 of the present invention;

FIG. 5 is a cross-sectional view showing a film formation apparatus according to an embodiment 4 of the present invention;

FIG. 6 is a cross-sectional view showing a film formation apparatus according to an embodiment 5 of the present invention;

FIG. 7 is a cross-sectional view showing a film formation apparatus according to an embodiment 6 of the present invention;

FIG. 8 is a cross-sectional view showing a film formation apparatus according to an embodiment 7 of the present invention;

FIG. 9 is a schematic cross-sectional view of an integrated circuit using a boron carbon nitride film formed by a film formation method according to an embodiment of the present invention; and

FIG. 10 is a schematic cross-sectional view of the integrated circuit using the boron carbon nitride film formed by the film formation method according to the embodiment of the present invention.

Corresponding reference characters indicate corresponding parts throughout the several views. The exemplifications set out herein illustrate at least one preferred embodiment of the invention, in one form, and such exemplifications are not to be construed as limiting the scope of the invention in any manner.

(Description of Symbols)

1 . . . Cylindrical vessel

2 . . . Inductively-coupled plasma generation part

3, 411 . . . Matching unit

4, 412 . . . High frequency power supply

5 . . . Nitrogen gas introduction part

6 . . . Substrate held part

7 . . . Heater

8 . . . Bias impressing part

9, 10, 29 . . . Introduction part

11 . . . Discharge part

50 . . . Plasma

60 . . . Substrate

61 . . . Boron carbon nitride film

310, 410 . . . Decomposition part

501 . . . Transistor

502 . . . Wiring

503 . . . Interlayer insulator thin film

504 . . . Protection film

### DETAILED DESCRIPTION OF THE INVENTION

Now, the film formation method of the present invention and embodiments of the film formation apparatus shall de described in detail using drawings.

(Embodiment 1)

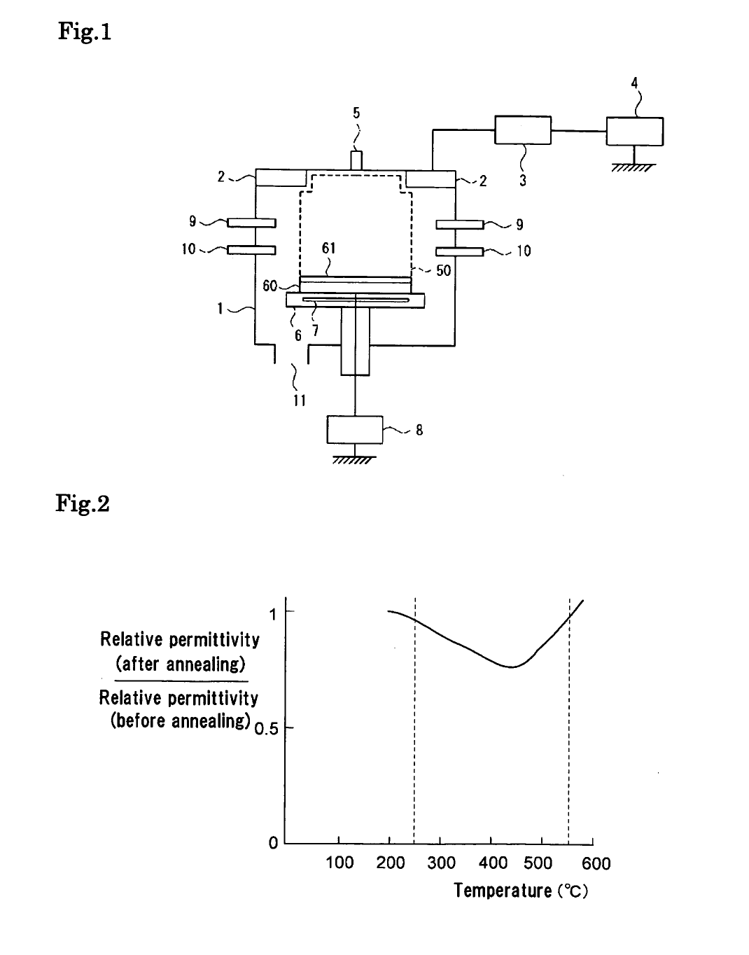

FIG. 1 shows a film formation apparatus according to an embodiment 1 of the present invention. An inductively-coupled plasma generation part 2 is disposed in a cylindrical vessel 1 and connected to a high frequency power supply 4 through a matching unit 3. The high frequency power supply 4 can supply a high frequency power from 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from room temperature to 600° C. by heater 7. An introduction part 8 for introducing boron chloride gas using hydrogen gas as a carrier is disposed in the cylindrical vessel 1.

Further, the cylindrical vessel 1 is provided with an introduction part 9 for introduction of hydrocarbon type gas. A discharge part 10 is provided below the substrate holding part 6.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

A p-type silicon substrate 60 is placed on the substrate holding part 6, and the interior of the vessel 1 is evacuated to 1×10⁻⁵ Torr. The substrate temperature is set to 300° C. Thereafter, nitrogen gas is introduced into the cylindrical vessel 1 from the introduction part 5. Plasma 50 is generated by supplying high frequency power (13.56 MHz) of 1 kw. Then, boron chloride is carried into the vessel 1 by using hydrogen gas as carrier gas. Moreover, the vessel 1 is supplied with methane gas. The gas pressure in the vessel 1 is adjusted to 0.6 Torr for synthesizing a boron carbon nitride film 61. Boron chloride and methane gas are not made into plasma, but boron chloride and methane gas are decomposed to form boron atoms and carbon atoms, and the obtained atoms react with nitrogen atoms to synthesize the boron carbon nitride film 61.

The chlorine combines with hydrogen atoms to form hydrogen chloride, limiting the potential intrusion of chlorine atoms into the film. After film formation, the substrate temperature is set to 400° C. by a heater mounted in the substrate holding part 6 and is then held for 10 min.

A boron carbon nitride film 61 in thickness 100 nm is deposited on the p-type silicon substrate, Au is vapor deposited on the boron carbon nitride film 61 and after the formation of electrodes, the capacitance—voltage characteristics is measured. Further, the relative permittivity is evaluated by using the capacitance value of the accumulation area of the metal/boron carbon nitride film/p-type silicon structure and the thickness of the boron carbon nitride film 61. The ratio of the relative permittivity of a film which is heat treated by changing the temperature and the relative permittivity evaluated without heating a similary prepared film is studied and shown in FIG. 2 as function of heat treatment temperature. The maintaining time was set to 10 min. The decrease of relative permittivity was observed after the heating to a maintained temperature of 250° C. to 550° C. For a film having a relative permittivity of 2.8 to 3.0 before the heating a low value of 2.2 to 2.4 in relative permittivity was obtained, after the heat treatment at a maintained temperature of 400° C.

Although nitrogen gas, boron chloride and methane gas were used as material gases for this embodiment, ammonium gas may also used as a nitrogen material. Moreover, diboron-hexahydride gas may also be used instead of boron chloride. Further, as for a carbon supply, hydrocarbon gases other than methane gas such as ethane gas, acetylene gas and so on and organic compounds of boron or nitrogen beginning with trimethyl boron may also be used.

(Embodiment 2)

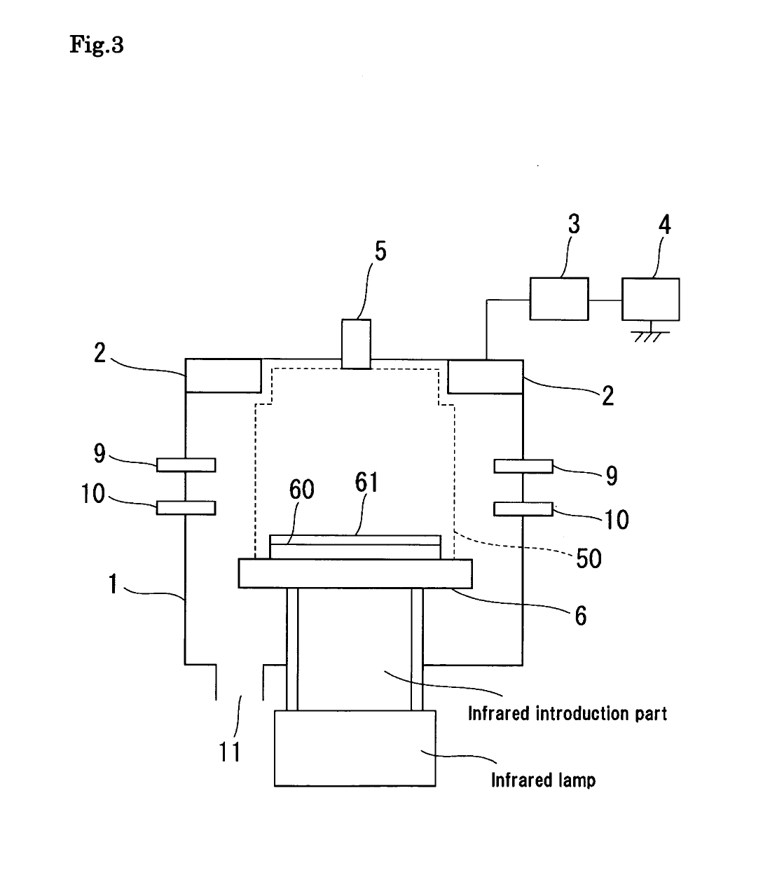

FIG. 3 is a schematic side view showing a film formation apparatus according to an embodiment 2 of the present invention. An inductively-coupled plasma generation part 2 is disposed in a cylindrical vessel 1 and connected to a high frequency power supply 4 through a matching unit 3. The high frequency power supply 4 can supply a high frequency power from 1 to 10 kw. Nitrogen gas is introduced from a nitrogen gas introduction part 5 into the cylindrical vessel 1 to generate plasma 50. A substrate 60 is placed on a substrate holding part 6 and an infrared heating part 7, composed of an infrared lamp and an infrared introduction part, is provided as a substrate heating means for heating the substrate holding part 6. The temperature of the substrate 60 can be set within a range from the room temperature to 600° C. by the infrared heating part 7. An introduction part 8 for introducing boron chloride gas using hydrogen gas as a carrier is disposed in the cylindrical vessel 1. Additionally, the cylindrical vessel 1 is provided with an introduction part 9 for introducing a hydrocarbon-type gas. A discharge part 10 is provided below the substrate holding part 6.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

A p-type silicon substrate 60 is placed on the substrate holding part 6, and the interior of the vessel 1 is evacuated to 1×10⁻⁵ Torr. The substrate temperature is set to 300° C. Thereafter, nitrogen gas is introduced into the cylindrical vessel 1 from the introduction part 5. Plasma 50 is generated by supplying high frequency power (13.56 MHz) of 1 kw. Then, boron chloride is carried into the vessel 1 by using hydrogen gas as the carrier gas. Moreover, the vessel 1 is supplied with methane gas. The gas pressure in the vessel 1 is adjusted to 0.6 Torr for synthesizing a boron carbon nitride film 61. Boron chloride and methane gas are not made into plasma, but boron chloride and methane gas are decomposed to form boron atoms and carbon atoms, and the obtained atoms react with nitrogen atoms to synthesize the boron carbon nitride film 61.

The chlorine combines with the hydrogen atoms to form hydrogen chloride, limiting the intrusion of chlorine atoms into the film. After film formation, the substrate holding part 6 is heated by the infrared lamp, and the film sample is held at 400° C. for 10 min.

The boron carbon nitride film 61 of a thickness of 100 nm is deposited on the p-type silicon substrate, and Au is vapor deposited on the boron carbon nitride film 61. After the formation of electrodes, a capacitance—voltage characteristic is measured, and the relative permittivity is evaluated by using the capacitance value of the accumulation area of the metal/boron carbon nitride film/p-type silicon structure and the thickness of the boron carbon nitride film 61. As a result, a low value of 2.0 to 2.4 in relative permittivity is obtainable.

(Embodiment 3)

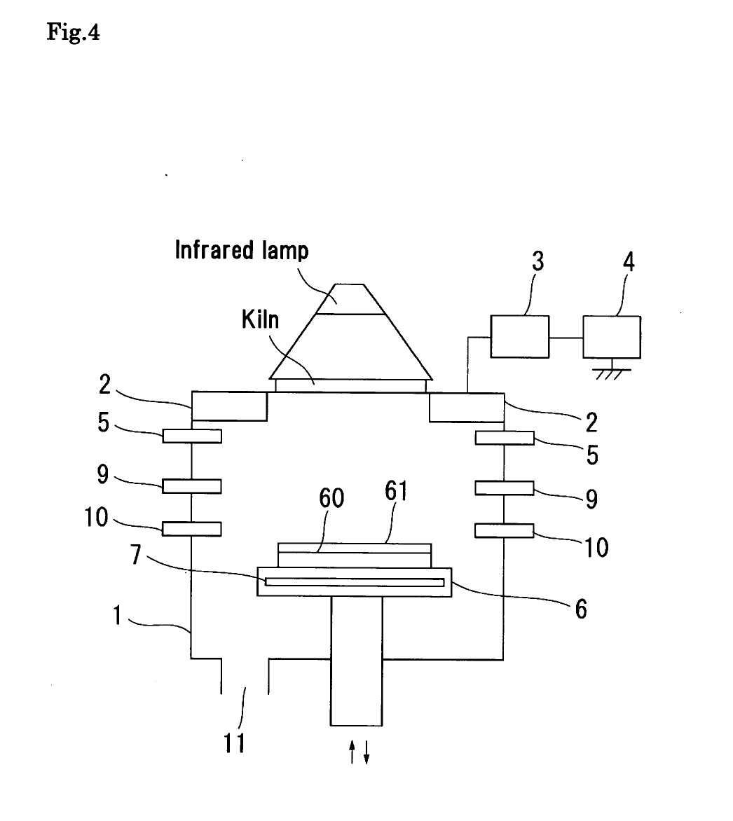

FIG. 4 is a schematic side view showing a film formation apparatus according to an embodiment 3 of the present invention. An inductively-coupled plasma generation part 2 is disposed in a cylindrical vessel 1 and is connected to a high frequency power supply 4 through a matching unit 3. The high frequency power supply 4 can supply a high frequency power from 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from the room temperature to 600° C. by using the heater 7. Moreover, a window (not labeled) is opened above the substrate holding part 6 of the film formation chamber, allowing the heating of the sample surface by using an infrared lamp 12. The substrate holding part 6 is allowed to move toward the window for heat suppression of the infrared lamp 12. An introduction part 8 for introducing boron chloride gas using hydrogen gas as a carrier is disposed in the cylindrical vessel 1. Further, the cylindrical vessel 1 is provided with an introduction part 9 for introducing a hydrocarbon type gas. A discharge part 10 is provided below the substrate holding part 6.

The supply flow range of respective gases can be set so that the flow rate ratio of nitrogen gas and boron chloride (nitrogen gas/boron chloride) is to be in a range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

A p-type silicon substrate 60 is placed on the substrate holding part 6 and the interior of the vessel 1 is evacuated to 1×10⁻⁵ Torr. The substrate temperature is set to 300° C. Thereafter, nitrogen gas is introduced into the cylindrical vessel 1 from the introduction part 5. Plasma 50 is generated by supplying high frequency power (13.56 MHz) of 1 kw. Then, boron chloride is carried into the vessel 1 by using hydrogen gas as the carrier gas. Moreover, the vessel 1 is supplied with methane gas. The gas pressure in the vessel 1 is adjusted to 0.6 Torr for synthesizing a boron carbon nitride film 61. Boron chloride and methane gas are not made into plasma, but boron chloride and methane gas are decomposed to form boron atoms and carbon atoms, and the obtained atoms react with nitrogen atoms to synthesize the boron carbon nitride film 61.

The chlorine combines with the hydrogen atoms to form hydrogen chloride, limiting the intrusion of chlorine atoms into the film. After film formation, the substrate holding part 6 is heated by the infrared lamp 12, and the film sample is held at 400° C. for 10 min.

The boron carbon nitride film 61 with a thickness of 100 nm is deposited on the p-type silicon substrate, and Au is vapor deposited on the boron carbon nitride film 61. After the formation of electrodes, a capacitance—voltage characteristic is measured and the relative permittivity is evaluated using the capacitance value of the accumulation area of the metal/boron carbon nitride film/p-type silicon structure and the thickness of the boron carbon nitride film 61. As a result, a low value of 2.0 to 2.4 in relative permittivity is obtainable.

(Embodiment 4)

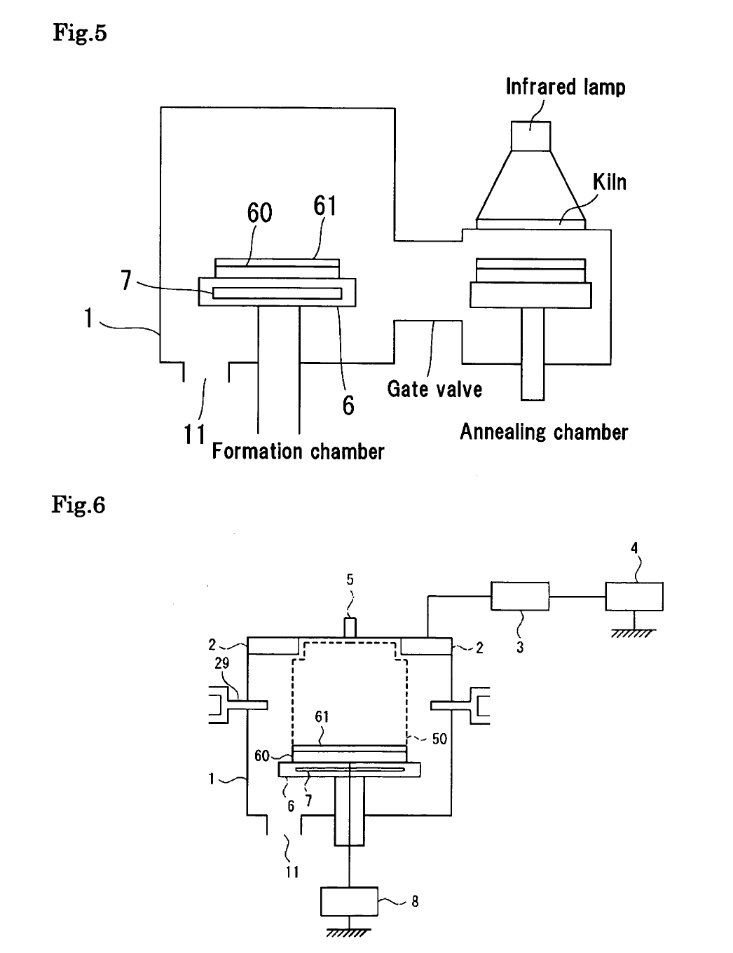

FIG. 5 is a schematic side view showing a film formation apparatus according to an embodiment 4 of the present invention. An inductively-coupled plasma generation part 2 is disposed in a cylindrical vessel 1 and is connected to a high frequency power supply 4 through a matching unit 3. The high frequency power supply 4 can supply a high frequency power from 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from room temperature to 600° C. by the heater 7. An introduction part 8 for introducing boron chloride gas using hydrogen gas as a carrier is disposed in the cylindrical vessel 1. Additionally, the cylindrical vessel 1 is provided with an introduction part 9 for introducing a hydrocarbon-type gas. A discharge part 10 is provided below the substrate holding part 6. An annealing chamber 14 is provided for the heating and then maintaining the temperature of the film 61 passed through the film formation chamber 1 and the gate valve 16, permitting heating of film 61 by the infrared lamp irradiation.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

A p-type silicon substrate 60 is placed on the substrate holding part 6, and the interior of the vessel 1 is evacuated to 1×1 0⁻⁵ Torr. The substrate temperature is set to 300° C. Thereafter, nitrogen gas is introduced into the cylindrical vessel 1 from the introduction part 5. Plasma 50 is generated by supplying high frequency power (13.56 MHz) of 1 kw. Then, boron chloride is carried into the vessel 1 by using hydrogen gas as the carrier gas. Further, the vessel 1 is supplied with methane gas. The gas pressure in the vessel 1 is adjusted to 0.6 Torr for synthesizing a boron carbon nitride film 61. Boron chloride and methane gas are not made into plasma, but boron chloride and methane gas instead are decomposed to form boron atoms and carbon atoms, and the obtained atoms react with nitrogen atoms to synthesize the boron carbon nitride film 61.

The chlorine combines with the hydrogen atoms to form hydrogen chloride, limiting the intrusion of chlorine atoms into the film. After film formation, the substrate temperature is set to 400° C. by the heater 7 fitted in the substrate holding part 6 and is held for 10 min. at that temperature.

The boron carbon nitride film 61 with a thickness of 100 nm is deposited on the p-type silicon substrate, Au is vapor deposited on the boron carbon nitride film 61. After the formation of the electrodes, a capacitance—voltage characteristic is measured, and the relative permittivity is evaluated by using the capacitance value of the accumulation area of the metal/boron carbon nitride film/p-type silicon structure and the thickness of the boron carbon nitride film 61. As a result, a low value of 2.0 to 2.4 in relative permittivity can be obtained.

(Embodiment 5)

FIG. 6 is a schematic side view showing a film formation apparatus according to an embodiment 5 of the present invention. An inductively-coupled plasma generation part 2 is disposed in a cylindrical vessel 1 and connected to a high frequency power supply 4 through a matching unit 3. The high frequency power supply 4 can supply a high frequency power in the range of 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from the room temperature to 500° C. by the heater 7. In addition, a bias can be impressed by an impressing/biasing part 8 upon the substrate 60 placed on the substrate holding part 6. An introduction part 29 is disposed for conducting boron chloride gas and a hydrocarbon-type gas using hydrogen gas as a carrier without mixing, such gases being conducted to a location just before the cylindrical vessel 1, joining both lines at the point of introduction of the cylindrical vessel 1, and introducing the resultant gas combination into the cylindrical vessel 1. A discharge part 11 is provided below the substrate holding part 6.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

The deposition of film 61 and the maintenance thereof in a heated state are executed, similar to the embodiment 1, by using this apparatus.

In this example also, a boron carbon nitride film of low relative permittivity can be obtained, similar to the embodiment 1.

In the introduction step for boron chloride and hydrocarbon gas of this embodiment effects similar to those yielded by the method of the embodiment 1 can be obtained by introducing boron chloride and hydrocarbon gas into the nitrogen plasma in the vessel 1.

(Embodiment 6)

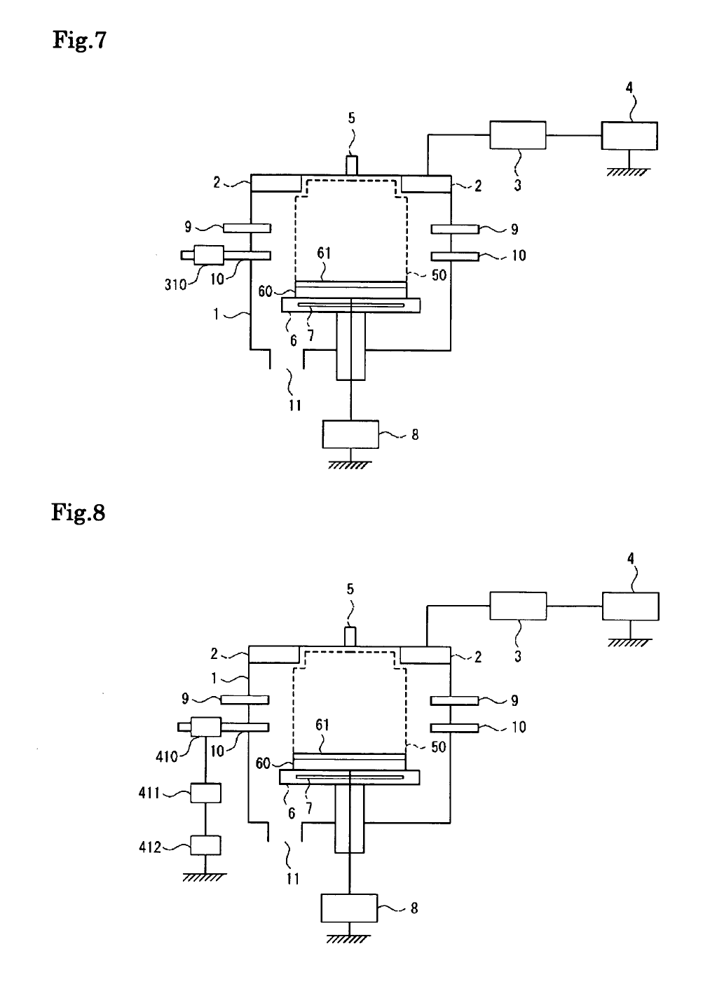

FIG. 7 is a schematic side view showing a film formation apparatus according to an embodiment 6 of the present invention. An inductively-coupled plasma generation part 2 is disposed in a cylindrical vessel 1 and connected to a high frequency power supply 4 through a matching unit 3. The high frequency power supply 4 can supply a high frequency power in the range of 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from the room temperature to 500° C. by the heater 7. In addition, a bias can be impressed by an impressing/biasing part 8 to the substrate 60 placed on the substrate holding part 6. An introduction part 9 is disposed for introducing boron chloride gas and a hydrocarbon-type gas using hydrogen gas as a carrier. In addition, a decomposition part 310 for decomposing carbonic hydrogen gas is disposed immediately before the cylindrical vessel 1 of the hydrocarbon-type gas introduction part 10. A discharge part 11 is provided below the substrate holding part 6.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

The deposition of film 61 and the maintenance thereof in a heated state are executed, similar to the embodiment 1, by using this apparatus.

The preparation of a film 61 having properties similar to the low dielectric constant boron carbon film obtained in the embodiment 1 and embodiment 5 can also be obtained in this example. Furthermore, the embodiment 3 permits the achievement of a low dielectric constant film under the condition where the flow of methane gas is reduced by about 20%, improves the intrusion efficiency of chlorine atoms into the deposited film, and has an effect of limiting methane gas consumption.

(Embodiment 7)

FIG. 8 is a schematic side view showing a film formation apparatus according to an embodiment 6 of the present invention. An inductively-coupled plasma generation part 2 is disposed in a cylindrical vessel 1 and connected to a high frequency power supply 4 through a matching unit 3. The high frequency power supply 4 can supply a high frequency power in the range of 1 to 10 kw. Nitrogen gas is introduced from a nitrogen gas introduction part 5 into the cylindrical vessel 1 to generate plasma 50. A substrate 60 is placed on a substrate holding part 6, and a heater 7 is mounted in the substrate holding part 6. The temperature of the substrate 60 can be set within a range from the room temperature to 500° C. by the heater 7. In addition, a bias can be impressed by an impressing/biasing part 8 to the substrate 60 placed on the substrate holding part 6. An introduction part 9 is disposed for introducing boron chloride gas and a hydrocarbon-type gas using hydrogen gas as a carrier. In addition, a decomposition part 310 for decomposing carbonic hydrogen gas is disposed immediately before the cylindrical vessel 1 of the hydrocarbon type gas introduction part 10. A discharge part 11 is provided below the substrate holding part 6.

The supply flow range of respective gases can be set so that the flow rate ratio of nitrogen gas and boron chloride (nitrogen gas/boron chloride) is to be in the range of 0.1 to 10.0, the flow rate ratio of hydrocarbon gas and boron chloride (hydrocarbon gas/boron chloride) 0.01 to 5.0, and the flow rate ratio of hydrogen gas and boron chloride (hydrogen gas/boron chloride) 0.05 to 5.0.

The deposition of film 61 and the maintenance thereof in a heated state are executed, similar to the embodiment 1, by using this apparatus.

This embodiment presents effects similar to the embodiment 6 and permits the achievement of a low dielectric constant film under the condition where the flow of methane gas is reduced by about 25%, improves the intrusion efficiency of chlorine atoms into the deposited film, and has an effect of limiting methane gas consumption.

Although methane gas is used as the hydrocarbon gas for the embodiments 1 to 7, various gases, beginning with ethane gas, acetylene gas and so on, may also be used.

(Embodiment 8)

Using an apparatus similar to the film formation apparatus shown in FIG. 1 used for the embodiment 1, the cylindrical vessel 1 is supplied with trimethyl boron instead of methane gas from the introduction part 10. As for other synthesis conditions such as substrate temperature, high frequency power and so on, conditions the same as those of the embodiment 1 are to be used.

In this embodiment also, effects similar to those of the embodiment 1 can be obtained.

(Embodiment 9)

Using an apparatus similar to the film formation apparatuses shown in FIG. 1 to 8 for the embodiments 5 to 8, the cylindrical vessel 1 is supplied with trimethyl boron instead of methane gas from the introduction part 10. As for other synthesis conditions such as substrate temperature, high frequency power and so on, conditions the same as those of the embodiments 2 to 4 are to be used.

In this embodiment also, a boron carbon nitride film of low dielectric constant could be obtained in a similar manner to the embodiment 5.

Although trimethyl boron, which is an organic material, is used for the carbon atom supply in the embodiment 8, any organic material can be used, provided that it contains boron and/or nitrogen.

Moreover, although nitrogen gas was used for generating nitrogen plasma in this embodiment, similar effects can be obtained by using ammonium gas.

(Embodiment 10)

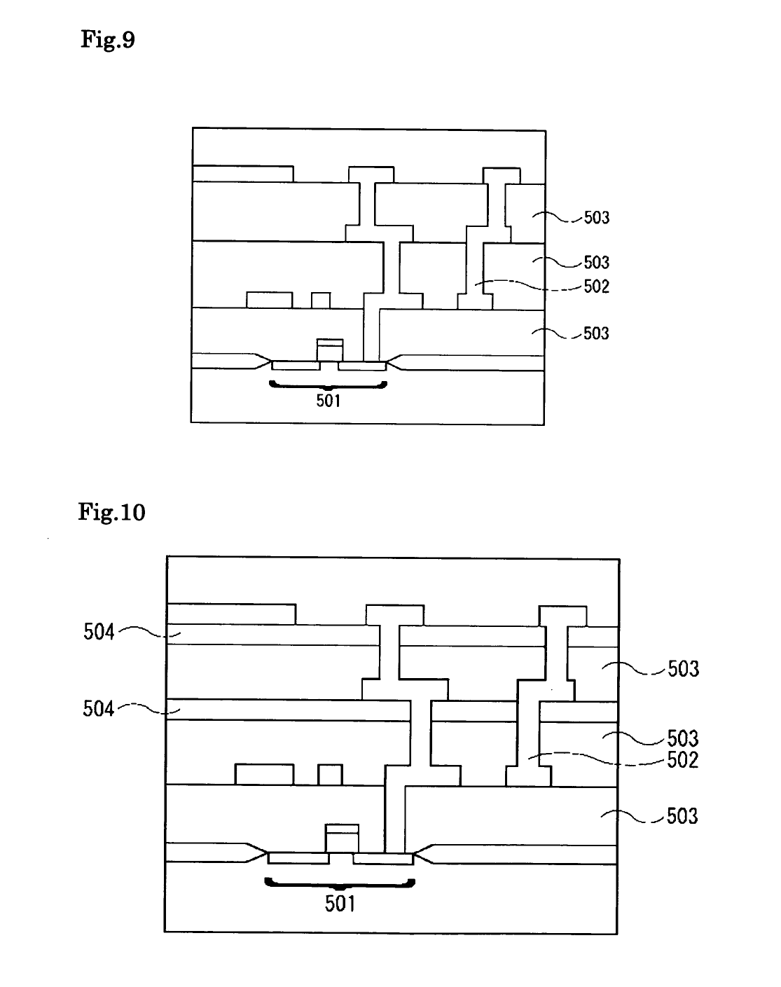

An example of an application of the boron carbon nitride film 61 formed by the film formation method of the present invention to an integrated circuit is described by using FIG. 9. It is necessary to use an interlayer insulator thin film 503 having a low dielectric constant between wirings in order make the wiring 502 a multilayer structure by a higher integration of transistors 501, and the boron carbon nitride film 61 formed by this film formation method can be used.

Mechanical resistance, moisture absorbability and so on can become problematic, in case of using an organic thin film or a porous film as interlayer insulator thin film 503. However, the boron carbon nitride film 61 formed by the film formation method of the present invention can be used as protection film 504 of the organic thin film or porous film as shown in FIG. 10. Such an incorporation of an organic thin film or porous film and the boron carbon nitride film make it possible to attain a dielectric constant lower than the relative permittivity that can be gained by a single layer of boron carbon nitride film and to obtain an effective relative permittivity lower than the order of 1.9.

### INDUSTRIAL APPLICABILITY

The film formation method of the present invention enables the formation of a mechanically and chemically stable boron carbon nitride film. This film also displays moisture absorption resistance and has a high heat conductivity. Further, such a film has a low dielectric constant, achieved by applying a heat treatment to a boron carbon nitride film prepared by the plasma vapor synthesis method.

In addition, the film formation apparatus of the present invention can form rapidly a boron carbon nitride film, having moisture absorption resistance, a high heat conductivity, and a low dielectric constant, by disposing a nitrogen gas introduction means and a plasma generation means in a cylindrical vessel and a means for holding the substrate under them, disposing a means of introduction of hydrocarbon or organic material as supply source of boron chloride and carbon between the nitrogen introduction means and the substrate holding means, using the plasma to cause a reaction of the nitrogen boron, and carbon atoms to form a boron carbon nitride film on the substrate, and, thereafter, providing a means for heating the substrate holding part and thereby heat treating the film.

The boron carbon nitride film according to the present invention can be used as a wiring interlayer, as an insulating thin film, or as a protection film for an integrated circuit. Stray capacitance can be lowered and frequency characteristics can be improved by using this film as a protection film of the semiconductor surface between a source and a gate and/or between a gate and a drain of a field effect transistor (FET) or a bipolar transistor aiming at the high frequency operation prepared with compound semiconductor (GaAs type, InP type, GaN type and so on).

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A film formation method for forming a low dielectric constant film, comprising the steps of:
generating a plasma in a film formation chamber;
making nitrogen atoms react with boron and carbon in the film formation chamber to thereby form a boron carbon nitrogen film on a substrate; and
then holding the obtained film in a heated state.

2. The film formation method of the low dielectric constant according to claim 1, wherein the holding temperature is set in an approximate range of 250° C. to 550° C.

3. The film formation method according to claim 1, further comprising the steps of:
activating mainly nitrogen atoms in the film formation chamber using the plasma; and
then making the activated atoms react with boron and carbon to form a boron carbon nitrogen film on the substrate.

4. The film formation method according to claim 3, wherein the activated atoms react with boron chloride gas and carbon using as a carrier gas of hydrogen gas to form the boron carbon nitrogen film on the substrate.

5. The film formation method according to claim 1, wherein a hydrocarbon gas is used for supplying carbon.

6. The film formation method of the low dielectric constant film according to claim 1, wherein an organic material gas is used for supplying carbon.

7. The film formation method according to claim 1, wherein a ratio of nitrogen gas flow rate and boron chloride gas flow rate is set to in an approximate range of 0.1 to 10.0.

8. The film formation method according to claim 1, wherein a ratio of hydrocarbon gas flow rate and boron chloride gas flow rate is set in an approximate range of 0.01 to 5.0.

9. The film formation method according to claim 1, wherein a ratio of organic material gas flow rate and boron chloride gas flow rate is set in an approximate range of 0.01 to 5.0.

10. A film formation apparatus, comprising:
a plasma generation means for generating plasma in a film formation chamber;
an introduction means for introducing nitrogen, boron and carbon materials in the film formation chamber;
a substrate holding means for holding a substrate below or within the plasma; and
a heating means for heating the substrate holding means.

11. The film formation apparatus according to claim 10, wherein the substrate holding means has a heater.

12. The film formation apparatus according to claim 10, wherein the heating means of the substrate holding means is an infrared lamp.

13. The film formation apparatus according to claim 10, wherein the introduction means further comprises:
a first introduction means for introducing nitrogen gas into the film formation chamber; and
a second introduction means for introducing boron and carbon materials between the first introduction means and the holding means.

14. The film formation apparatus according to claim 13, wherein the second introduction means is constituted so as to introduce boron and carbon independently.

15. The film formation apparatus according to claim 10, wherein the introduction means further comprises:
a first introduction means for introducing nitrogen gas into the film formation chamber; and
a second introduction means for introducing boron chloride gas and hydrocarbon gas into the film formation chamber below the first introduction means using hydrogen gas as a carrier gas.

16. The film formation apparatus according to claim 10, wherein the introduction means further comprises:
a first introduction means for introducing nitrogen gas into the film formation chamber; and
a second introduction means for introducing boron chloride gas and organic material gas using as a carrier gas of hydrogen gas in the film formation chamber below the first introduction means.

17. The film formation apparatus according to claim 16, wherein the second introduction means has a decomposition part for decomposing the organic material on the way thereof.

18. The film formation apparatus according to claim 17, wherein the decomposition part is constituted so as to heat the organic material.

19. An insulating film produced by the method according to claim 1.

20. A semiconductor device using a film produced by the method according to claim 1 as an interlayer film of wiring.

21. A semiconductor device using a film produced by the method according to claim 1 as a protection film.

22. A semiconductor device using a film produced by the method according to claim 1 as a protection film of a semiconductor surface at least one of between a source and a gate and between a gate and a drain of one of a field effect transistor and a bipolar transistor.
